(19) United States
(12) Patent Application Publication
(10) Pub. No.: US 2022/0348789 A1
(43) Pub. Date: Nov. 3, 2022

(54) SURFACE MODIFIED SILANIZED COLLOIDAL SILICA PARTICLES

(71) Applicant: Rohm and Haas Electronics Materials CMP Holdings, Inc., Newark, DE (US)

(72) Inventor: Changzai CHI, Hockessin, DE (US)

(21) Appl. No.: 17/697,647

(22) Filed: Mar. 17, 2022

Related U.S. Application Data
(60) Provisional application No. 63/178,046, filed on Apr. 22, 2021.

(51) Int. Cl. C09G 1/02; C01B 33/141; C09K 3/14; C01B 33/149

(52) U.S. Cl. CPC C09G 1/02; C01B 33/1417; C09K 3/1463; C01B 33/149; C09K 3/1409; B82Y 30/00

(57) ABSTRACT

Modified silanized colloidal silica particles are reaction products of silanized colloidal silica particles having epoxy moieties with nitrogen of amines to form stable and tunable modified silanized colloidal silica particles. The modified silanized colloidal silica particles can be used as an abrasive in chemical mechanical polishing of various substrates.

### FIELD OF THE INVENTION

The present invention is directed to surface modified silanized colloidal silica particles. More specifically, the present invention is directed to surface modified silanized colloidal silica particles which are reaction products of epoxy moieties of silanized colloidal silica particles with nitrogen of amine compounds to provide surface modified silanized colloidal silica particles which are stable and tunable for the chemical mechanical polishing of substrates.

### BACKGROUND OF THE INVENTION

Aqueous colloidal silica particle dispersions have long been used in many applications, such as in coating materials to improve wear resistance and in chemical mechanical polishing (CMP) slurries as abrasive particles. Silica is the most widely used abrasive particle in the CMP industry. In aqueous solutions, the surface of native silica particles is covered with silanol groups and isoelectric point of unmodified silica is at about pH=2. For this reason, the unmodified silica particle generally has a negative surface charge in the pH range of about 2-11, which is the pH range for many applications. At a high pH of 10 and above, silica particles are highly negatively charged, and dispersions are stabilized by the charge repulsion between particles. As pH drops, the dispersion become less stable due to the reduced surface charge. Particle dispersions are very unstable in the pH range of 5-7 and usually rapidly forms aggregates. In addition, the presence of electrolyte in the formulations in many applications reduces electrostatic repulsion between particles and colloidal stability. For many applications, including CMP slurries and coating formulations, it is highly desirable to improve the stability of silica particles in formulations when the pH is 8 or below.

Silane modifications have been widely used to alter surface properties of silica particles and improve stability at various conditions. Two most commonly used types of silanes are epoxysilanes and aminosilanes. It is believed that epoxy groups can be hydrolyzed into diols and provide steric stability. Sterically stabilized colloids are less sensitive to electrolytes than electrostatically stabilized colloids. However, epoxysilane modified particles can become unstable as pH drops.

Aminosilanes are another group of silanes that have been widely used to modify silica particles. The presence of amino groups increases the positive charge of particles at acid pH. In U.S. Pat. No. 9,028,572, aminopropyltriethoxysilane (APS) was used to modify the surface of the silica particles. The particles were then used as abrasives for CMP slurries. The data from the examples showed that aminosilane modified silica particles were positively charged at acidic pH. However, surface modified aminosilanes are self-catalytic and it is often difficult to control reaction kinetics which can lead to particle agglomeration. In addition, the formation of oligomeric species among aminosilane molecules can lead to low modification efficacy with only a fraction of the aminosilanes attached to the particle surface. For example, the data calculated in Example 9 of U.S. Pat. No. 9,028,572 showed that the percentage of silane attached onto silica could be as low as 50%. Free silane in the solution can have detrimental effects on stability and polishing performance of such particles.

Accordingly, there is a need for improved silanized colloidal silica particles for the chemical mechanical polishing of substrates.

### SUMMARY OF THE INVENTION

The present invention is directed to a silanized colloidal silica particle comprising a reaction product of an epoxy functionality of the silanized colloidal silica particle with a nitrogen of an amine.

The present invention is also directed to a silanized colloidal silica particle having the structure:

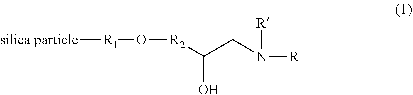

wherein R₁ and R₂ are independently chosen from linear or branched C₁-C₅ alkylene; R and R′ are independently chosen from hydrogen, linear or branched C₁-C₄ alkyl, linear or branched hydroxy C₁-C₄ alkyl, linear or branched alkoxy C₁-C₄ alkyl, quaternary amino C₁-C₄ alkyl, substituted or unsubstituted, linear or branched amino C₁-C₄ alkyl, wherein substituent groups of the substituted amino alkyl include linear or branched C₁-C₄ alkyl on a nitrogen of the amino C₁-C₄ alkyl group, substituted or unsubstituted guanidyl group, wherein substituent groups on the substituted guanidyl group are chosen from C₁-C₂ alkyl on a nitrogen of the guanidyl group, and R′ and R independently can be a moiety having the formula:

H₂N—[—(CH₂)ₙ—NH—]ₘ—(CH₂)ₙ— (II)

wherein n and m are independently integers from 2-4; and R and R′ can be taken together with their atoms to form a substituted or unsubstituted heterocyclic nitrogen and carbon six membered ring, wherein substituent groups are chosen from C₁-C₂ alkyl groups.

The present invention is further directed to a chemical mechanical polishing composition comprising a silanized colloidal silica particle comprising a reaction product of an epoxy functionality of the silanized colloidal silica particle with a nitrogen of an amine;

water;
optionally an oxidizing agent;
optionally a complexing agent;
optionally a source of iron (III) ions;
optionally a corrosion inhibitor;
optionally a surfactant;
optionally a defoaming agent;
optionally biocide; and
optionally a pH adjustor.

The present invention is additionally directed to a chemical mechanical polishing method comprising: providing a substrate comprising a metal or a dielectric or combination of a metal and a dielectric;

providing a chemical mechanical polishing composition comprising a silanized colloidal silica particle, wherein the silanized colloidal silica particle comprises a reaction product of an epoxy functionality of the silanized colloidal silica particle with a nitrogen of an amine;
water;
optionally an oxidizing agent;
optionally a complexing agent;
optionally a source of iron (III) ions;
optionally a corrosion inhibitor;
optionally a surfactant;
optionally a defoaming agent;
optionally biocide; and
optionally a pH adjustor;
providing a chemical mechanical polishing pad, having a polishing surface; creating dynamic contact at an interface between the chemical mechanical polishing pad and the substrate; and dispensing the chemical mechanical polishing composition onto the polishing surface of the chemical mechanical polishing pad at or near the interface between the chemical mechanical polishing pad and the substrate; wherein some of the metal or some of the dielectric or portions of the metal and the dielectric are polished away from the substrate.

The present invention is even further directed to a chemical mechanical polishing method comprising: providing a substrate comprising a metal or a dielectric or a combination of a metal and a dielectric;

providing a chemical mechanical polishing composition comprising:
a silanized colloidal silica particle having the structure:

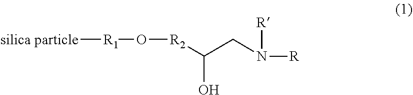

wherein R₁ and R₂ are independently chosen from linear or branched C₁-C₅ alkylene; R and R′ are independently chosen from hydrogen, linear or branched C₁-C₄ alkyl, linear or branched hydroxy C₁-C₄ alkyl, linear or branched alkoxy C₁-C₄ alkyl, quaternary amino C₁-C₄ alkyl, substituted or unsubstituted, linear or branched amino C₁-C₄ alkyl, wherein substituent groups of the substituted amino C₁-C₄ alkyl group include linear or branched C₁-C₄ alkyl on a nitrogen of the amino C₁-C₄ alkyl group, substituted or unsubstituted guanidyl group, wherein substituent groups on the substituted guanidyl group are chosen from C₁-C₂ alkyl on a nitrogen of the guanidyl group, and R′ and R independently can be a moiety having the formula:

H₂N—[—(CH₂)ₙ—NH—]ₘ—(CH₂)ₙ— (II)

wherein n and m are independently integers from 2-4; and R and R′ can be taken together with their atoms to form a substituted or unsubstituted heterocyclic nitrogen and carbon six membered ring, wherein substituent groups are chosen from C₁-C₂ alkyl groups;
water;
optionally an oxidizing agent;
optionally a complexing agent;
optionally a source of iron (III) ions;
optionally a corrosion inhibitor;
optionally a surfactant;
optionally a defoaming agent;
optionally biocide; and
optionally a pH adjustor;
providing a chemical mechanical polishing pad, having a polishing surface; creating dynamic contact at an interface between the chemical mechanical polishing pad and the substrate; and dispensing the chemical mechanical polishing composition onto the polishing surface of the chemical mechanical polishing pad at or near the interface between the chemical mechanical polishing pad and the substrate; wherein some of the metal or some of the dielectric or portions of the metal and dielectric are polished away from the substrate.

The silanized colloidal silica particles of the present invention can be used as abrasives in chemical mechanical polishing substrates containing metal features or layers and dielectric structures. The silanized colloidal silica particles of the present invention can be tuned to control polishing performance by modifying the epoxysilane joined to the colloidal silica particles and by modifying the amine covalently bonded to the epoxysilane.

### DETAILED DESCRIPTION OF THE INVENTION

As used throughout this specification the following abbreviations have the following meanings, unless the context indicates otherwise: ° C.=degrees Centigrade; g=grams; kPa=kilopascal; Å=angstroms; DI=deionized; ppm=parts per million; m=meter; mm=millimeters; nm=nanometers; mA=milliamps; mM=millimoles; μL=micro-liters; min=minute; hr=hour; rpm=revolutions per minute; lbs=pounds; H=hydrogen; Cu=copper; Mn=manganese; Fe=iron; N=nitrogen; O=oxygen; W=tungsten; Ti=titanium; TiN=titanium nitride; Co=cobalt; HNO₃=nitric acid; KOH=potassium hydroxide; HO=hydroxyl; SiN=silicon nitride; Si—OH=silanol group; IC=ion chromatography; wt %=percent by weight; IEP=isoelectric point; BET=Bunauer-Emmett-Teller; RR=removal rate; and Ex=example.

The term “chemical mechanical polishing” or “CMP” refers to a process where a substrate is polished by means of chemical and mechanical forces alone and is distinguished from electrochemical-mechanical polishing (ECMP) where an electric bias is applied to the substrate. The terms “compositions”, “dispersions” and “slurries” are used interchangeably throughout the specification. The term “silane” and “epoxysilane” are used interchangeably throughout the specification. The term “functionality” means a moiety of a molecule which has a decisive influence on the molecules reactivity. The term “TEOS” means the silicon dioxide formed from tetraethyl orthosilicate (Si(OC₂H₅)₄). The term “alkylene” means a bivalent saturated aliphatic group or moiety regarded as derived from an alkene by opening of the double bond, such as ethylene: —CH₂—CH₂—, or from an alkane by removal of two hydrogen atoms from different carbon atoms. The term “methylene group” means a methylene bridge or methanediyl group with a formula: —CH₂— where a carbon atom is bound to two hydrogen atoms and connected by single bonds to two other distinct atoms in the molecule. The term “alkyl” means an organic group with a general formula: CₙH₂ₙ₊₁ where “n” is an integer and the “yl” ending means a fragment of an alkane formed by removing a hydrogen. The term “moiety” means a part or a functional group of a molecule. The terms “a” and “an” refer to both the singular and the plural. All percentages are by weight, unless otherwise noted. All numerical ranges are inclusive and combinable in any order, except where it is logical that such numerical ranges are constrained to add up to 100%.

The present invention is directed to a silanized colloidal silica particle comprising (preferably, consisting of) a reaction product of an epoxy functionality of a silanized colloidal silica particle with a nitrogen of an amine. Epoxysilane compounds react with silanol groups on the surfaces of the colloidal silica particles to form covalent siloxane bonds (Si—O—Si) with the silanol groups or, alternatively, the epoxysilane compounds are linked to the silanol groups by, for example, hydrogen bonding. In the second step, the first reaction product which includes a free epoxy functionality is reacted with an amine compound in an addition reaction. A hydrogen atom is removed from a nitrogen atom of the amine and the nitrogen atom from the amine reacts with the epoxy functionality to form the final modified colloidal silica particle. Substantially all the amine reagents react with the epoxy functionalities to form a covalent bond.

The colloidal silanized silica particles of the present invention can be made, preferably, by making a 30-60% pre-hydrolyzed aqueous silane solution by mixing desirable amounts weight by weight of epoxysilane and DI water for about 0.5-2 hr. Silane surface modification is done by slowly adding the 30-60% pre-hydrolyzed aqueous epoxysilane solution into dispersions of colloidal silica particles over a period of about 1-10 min. DI water is then mixed with the silane modified colloidal silica particles to make dispersions. The dispersions can then be further aged at room temperature for at least 1 hr.

Amine solutions are then added to the silane modified colloidal silica particle dispersions with mixing at room temperature. The dispersions are aged at room temperature for about 1-10 days or at 50-60° C. for about 1-24 hr. The dispersions are then diluted with DI water and pH is adjusted with acid, such as inorganic acids chosen from nitric acid, hydrochloric acid, sulfuric acid or phosphoric acid, or an organic acid, to a pH in the range of 4-7.

The properties and performance of surface modified particles can depend on numbers of functional groups per surface area created by modification. Particles with different sizes or shapes have different specific surface areas, thus they require different amounts of epoxysilane and amine to achieve the same degree of functionalization. For this reason, degree of surface functionalization depends on both the amount of epoxysilane and amine added during the surface modification and total particle surface area available for surface reaction. For ease of comparison between particles with different specific surface area, the number of epoxysilane or amine molecules per nm² of surface area of particle is calculated from the amount of epoxysilane and amine added. This can be done using the following equation.

Ns=(Ws/Mw×NA)/(SSA×Wp×10¹⁸) Equation (1)
Ns: Number of epoxysilane or amine per nm² of surface area of particle in number of molecules/nm².
Ws: Weight of epoxysilane or amine added in grams.
Mw: Molecular weight, g/mol of epoxysilane or amine
NA: Avogadro's number, 6.022×10²³ mol⁻¹
SSA: Specific surface area of particle in m²/g
Wp: Total weight of particle in solution.
SSA can be obtained by BET surface area measurement or Sears titration (determination of specific surface area of colloidal silica by titration with sodium hydroxide, G. W. Sears, Anal. Chem. 1956, 28, 12, 1981-1983.), both processes are well known in the art.

Preferably, epoxysilane compounds are mixed and reacted with the colloidal silica particles to provide a molecule of epoxysilane compound on the surface of the particle of 0.05-1 molecules of silane per nm² of surface area, more preferably, from 0.1-0.8 molecules of silane per nm² of surface area, even more preferably, from 0.15-0.6 molecules of silane per nm² of surface area.

The weight ratio of epoxysilane/silica is in the range of about 0.0005 to 0.05, more preferably, from 0.001to 0.025, even more preferably, from 0.002 to 0.02.

Preferably, amine compounds are included in amounts such that one molecule of the amine covers 0.05-1 molecules of amine per nm² of particle surface area, more preferably, from 0.1-0.8 molecules of amine per nm² of particle surface area. The amine is calculated by the same process as that of the epoxysilane.

The weight ratio of amine/silica is in the range of about 0.0001 to 0.05, more preferably, from 0.0002 to 0.02, even more preferably, from 0.0005 to 0.01.

Weight in grams of the epoxysilane or amine can be calculated using the following equation.

Ws=(Ns×SSA×Wp×10¹⁸/NA)×Mw Equation (2)
Ns: Number of epoxysilane or amine per nm² of surface area of particle in number of molecules/nm².
Ws: Weight of epoxysilane or amine added in grams.
Mw: Molecular weight, g/mol of epoxysilane or amine
NA: Avogadro's number, 6.022×10²³ mol⁻¹
SSA: Specific surface area of particle in m²/g
Wp: Total weight of particles in solution.

Epoxysilanes include, but are not limited to, 5,6-epoxyhexyltriethoxysilane, 2-(3,4-epoxycyclohexyl)ethyltrimethoxsilane, and glycidoxysilanes. Preferably, the epoxysilanes are glycidoxysilanes. Exemplary glycidoxysilane compounds are (3-glycidoxypropyl) trimethoxysilane, γ-glycidoxypropylmethyl diethoxysilane, γ-glycidoxypropyl trimethoxysilane and (3-glycidoxypropyl) hexyltrimethoxysilane.

Amines include amine compounds which have at least one hydrogen atom which can be removed from a nitrogen in an addition reaction to enable the nitrogen to react with the epoxy functionality of the epoxysilane. Such amines include amine compounds having a primary or secondary amine functionality. Preferably, the amine has a primary amine functionality. Exemplary amines are ethanolamine, N-methylethanolamine, butylamine, dibutylamine, 3-ethoxypropylamine, ethylenediamine, N,N-dimethylethylenediamine, 3-(dimethylamino)-1-propylamine, 3-(diethylamino) propylamine, (2-aminoethyl) trimethylammonium chloride hydrochloride, triethylenetetramine, teraethylenepentamine, pentaethylenehexamine, guanidine, guanidine acetate and 1,1,3,3-tetramethylguanidine.

Preferably, the reaction products of the epoxy functionality of the silanized colloidal silica particle and the amines of the present invention are modified silanized colloidal silica particles having the general structure:

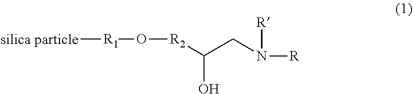

wherein R₁ and R₂ are independently chosen from linear or branched C₁-C₅ alkylene; R and R′ are independently chosen from hydrogen, linear or branched C₁-C₄ alkyl, linear or branched hydroxy C₁-C₄ alkyl, linear or branched alkoxy C₁-C₄ alkyl, quaternary amino C₁-C₄ alkyl, substituted or unsubstituted, linear or branched amino C₁-C₄ alkyl, wherein substituent groups of the substituted amino C₁-C₄ alky group include linear or branched C₁-C₄ alkyl on a nitrogen of the amino C₁-C₄ alkyl group, substituted or unsubstituted guanidyl group, wherein substituent groups of the substituted guanidyl group are chosen from C₁-C₂ alkyl on a nitrogen of the guanidyl group, and a moiety having the formula:

H₂N—[—(CH₂)ₙ—NH—]ₘ—(CH₂)ₙ— (II)

wherein n and m are independently integers from 2-4; and R and R′ can be taken together with their atoms to form a substituted or unsubstituted heterocyclic nitrogen and carbon six membered ring, wherein substituent groups are chosen from C₁-C₂ alkyl groups.

Preferably, R₁ and R₂ are independently chosen from linear C₁-C₅ alkylene groups, such as —(CH₂)ₜ— where t is an integer of 1-5, more preferably, R₁ is C₃ alkylene or propylene, such as —(CH₂)ₜ— where t=3 and R₂ is C₁ alkylene or methylene, such as —(CH₂)ₜ— where t=1. Preferably, R and R′ are independently chosen from hydrogen, hydroxy C₁-C₃ alky, linear or branched C₁-C₄ alkyl, alkoxy C₁-C₄ alkyl, substituted or unsubstituted amino C₁-C₄ alkyl, wherein when the nitrogen of the amino is substituted, preferably, the nitrogen is substituted with one or two C₁-C₂ alkyl groups, and R′ and R independently can be a moiety having the formula:

H₂N—[—(CH₂)ₙ—NH—]ₘ—(CH₂)ₙ— (II)

wherein n and m are independently integers from 2-4. More preferably, R and R′ are independently chosen from hydrogen, hydroxy C₂-C₃ alkyl, unsubstituted amino C₂-C₃ alkyl, and a moiety having the formula:

H₂N—[—(CH₂)ₙ—NH—]ₘ—(CH₂)ₙ— (II)

wherein n is 2 and m is an integer from 2-4.

While it is envisioned that the modified silanized colloidal silica particles of the present invention can be used in various industries, preferably, the modified silanized colloidal silica particles of the present invention are used as abrasives in chemical mechanical polishing of metals, dielectrics or substrates which include a combination of metals and dielectrics. The chemical mechanical polishing compositions of the present invention comprise a silanized colloidal silica particle comprising (preferably consisting of) a reaction product of an epoxy functionality of the silanized colloidal silica particle with a nitrogen of an amine, as described above.

Preferably, the reaction product of the epoxy functionality and the amine has the general structure:

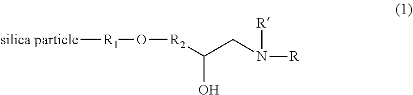

wherein R₁ and R₂ are independently chosen from linear or branched C₁-C₅ alkylene; R and R′ are independently chosen from hydrogen, linear or branched C₁-C₄ alkyl, linear or branched hydroxy C₁-C₄ alkyl, linear or branched alkoxy C₁-C₄ alkyl, quaternary amino C₁-C₄ alkyl, substituted or unsubstituted, linear or branched amino C₁-C₄ alkyl, wherein substituent groups on the substituted amino C₁-C₄ alkyl group include linear or branched C₁-C₄ alkyl on a nitrogen of the amino C₁-C₄ alkyl group, substituted or unsubstituted guanidyl group, wherein substituent groups of the substituted guanidyl group are chosen from C₁-C₂ alkyl on a nitrogen of the guanidyl group, and R′ and R independently can be a moiety having the formula:

H₂N—[—(CH₂)ₙ—NH—]ₘ—(CH₂)ₙ— (II)

wherein n and m are independently integers from 2-4; and R and R′ can be taken together with their atoms to form a substituted or unsubstituted heterocyclic nitrogen and carbon six membered ring, wherein substituent groups are chosen from C₁-C₂ alkyl groups.

Preferably, R₁ and R₂ are independently chosen from linear C₁-C₅ alkylene groups, such as —(CH₂)ₜ— where t is an integer of 1-5, more preferably, R₁ is C₃ alkylene or propylene, such as —(CH₂)ₜ— where t=3 and R₂ is C₁ alkylene or methylene, such as —(CH₂)ₜ— where t=1. Preferably, R and R′ are independently chosen from hydrogen, hydroxy C₁-C₃ alky, linear or branched C₁-C₄ alkyl, alkoxy C₁-C₄ alkyl, substituted or unsubstituted amnio C₁-C₄ alkyl, wherein when the nitrogen of the amino is substituted, preferably, the nitrogen is substituted with one or two C₁-C₂ alkyl groups, and R′ and R independently can be a moiety having the formula:

H₂N—[—(CH₂)ₙ—NH—]ₘ—(CH₂)ₙ— (II)

wherein n and m are independently integers from 2-4. More preferably, R and R′ are independently chosen from hydrogen, hydroxy C₂-C₃ alkyl, unsubstituted amino C₂-C₃ alkyl, and a moiety having the formula:

H₂N—[—(CH₂)ₙ—NH—]ₘ—(CH₂)ₙ— (II)

wherein n is 2 and m is an integer from 2-4.

The modified silanized colloidal silica abrasive particles are included in the chemical mechanical polishing compositions of the present invention in amounts of greater than 0wt % but not more than 5wt %, preferably, greater than 0wt % but not more than 3wt %, more preferably, greater than 0wt % but not more than 2wt %, even more preferably, 1-3wt %, most preferable, 1-2wt % of the chemical mechanical polishing composition.

Preferably, the modified silanized colloidal silica particles of the present invention have an average diameter ranging from 10 nm to 150 nm, more preferably, from 20 nm to 100 nm, even more preferably, from 30 nm to 80 nm, as measured by dynamic light (DL) scattering techniques. Suitable particle size measuring instruments are available from, for example, Malvern Instruments (Malvern, UK).

IEP of the modified silanized colloidal silica particles of the present invention ranges from pH 4 to 8.5, preferably, pH 5.5 to 8 to provide well dispersed modified silanized colloidal silica particles in an aqueous composition which resist aggregation in slurries having an acid pH. IEP can be measured by conventional methods and apparatus. An example of a method for determining the IEP of the particles is by titration using ZetaAcoustic (ZA500) by Mass Applied Sciences.

Colloidal silica particles used to prepare the modified silanized colloidal silica particles of the present invention can be spherical, nodular, bent, elongated or cocoon shaped colloidal silica particles. Preferably, the surface area of the colloidal silica particles is 20 m²/g and greater, more preferably, from 20 m²/g to 200 m²/g, most preferably, from 30 m²/g to 150 m²/g. Such colloidal silica particles are commercially available. Examples of commercially available colloidal silica particles are Fuso BS-3 and Fuso SH-3 both available from Fuso Chemical Co., LTD.

Water is also included in the chemical mechanical polishing compositions of the present invention. Preferably, the water contained in the chemical mechanical polishing compositions is at least one of deionized and distilled to limit incidental impurities.

Optionally, the chemical mechanical polishing compositions of the present invention include one or more oxidizing agents, wherein the oxidizing agents are selected from the group consisting of hydrogen peroxide (H₂O₂), monopersulfates, iodates, magnesium perphthalate, peracetic acid and other per-acids, persulfate, bromates, perbromate, persulfate, peracetic acid, periodate, nitrates, iron salts, cerium salts, Mn (III), Mn (IV) and Mn (VI) salts, silver salts, copper salts, chromium salts, cobalt salts, halogens, hypochlorites and a mixture thereof. Preferably, the oxidizing agent is selected from the group consisting of hydrogen peroxide, perchlorate, perbromate, periodate, persulfate and peracetic acid. Most preferably, the oxidizing agent is hydrogen peroxide.

The chemical mechanical polishing composition can contain 0.01-10wt %, preferably, 0.1-5wt %; more preferably, 1-3wt % of an oxidizing agent.

Optionally, the chemical mechanical polishing compositions of the present invention can include one or more corrosion inhibitors. Conventional corrosion inhibitors can be used. The choice of corrosion inhibitors can depend on the metal on the substrate which is being polished. Corrosion inhibitors include, but are not limited to, benzotriazole; 1,2,3-benzotriazole; 1,6-dimethyl-1,2,3-benzotriazole; 1-(1,2-dicarboxyethyl)benzotriazole; 1-[N,N-bis(hydroxylethyl)aminomethyl]benzotrizole; or 1-(hydroxylmethyl)benzotriazole.

Corrosion inhibitors can be included in the chemical mechanical polishing composition in conventional amounts. Preferably, corrosion inhibitors are included in amounts of 0.1-1000 ppm, more preferably, from 50-500 ppm, even more preferably, from 100-450 ppm.

Optionally, the chemical mechanical polishing compositions of the present invention can include a source of iron (III) ions, wherein the source of iron (III) ions is selected from the group consisting iron (III) salts. Most preferably the chemical mechanical polishing composition contains a source of iron (III) ions, wherein the source of iron (III) ions is ferric nitrate nonahydrate, (Fe(NO₃)₃.9H₂O).

The chemical mechanical polishing composition can contain a source of iron (III) ions sufficient to introduce 1 to 200 ppm, preferably, 5 to 150 ppm, more preferably, 7.5 to 125 ppm, most preferably, 10 to 100 ppm of iron (III) ions to the chemical mechanical polishing composition. In a particularly preferred chemical mechanical polishing composition the source of iron (III) ions is included in amounts sufficient to introduce 10 to 150 ppm to the chemical mechanical polishing composition.

Optionally, the chemical mechanical polishing composition contains a pH adjusting agent. Preferably, the pH adjusting agent is selected from the group consisting of inorganic and organic pH adjusting agents. More preferably, the pH adjusting agent is selected from the group consisting of inorganic acids and inorganic bases. Inorganic acids include, but are not limited to, nitric acid, sulfuric acid, hydrochloric acid and phosphoric acid. Inorganic bases include, but are not limited to, potassium hydroxide, sodium hydroxide and ammonium hydroxide. Further preferably, the pH adjusting agent is selected from the group consisting of nitric acid and potassium hydroxide. Most preferably, the pH adjusting agent is nitric acid. Sufficient amounts of the pH adjusting agent are added to the chemical mechanical polishing composition to maintain a desired pH or pH range of 4-7.

Preferably in the chemical mechanical polishing compositions of the present invention, the pH of the chemical mechanical polishing composition is below the IEP of the aqueous compositions or aqueous dispersions of the modified silanized colloidal silica particles of the present invention to maintain particle stability during chemical mechanical polishing of substrates. Further, chemical mechanical polishing compositions of the present invention with pH values below the IEP of aqueous dispersions of the modified silanized colloidal silica particles enable good physical contact and good polishing interaction with dielectric substrates, such as TEOS and SiN.

Optionally, the chemical mechanical polishing composition contains biocides, such as KORDEK™ MLX (9.5-9.9% methyl-4-isothiazolin-3-one, 89.1-89.5% water and ≤1.0% related reaction product) or KATHON™ ICP III containing active ingredients of 2-methyl-4-isothiazolin-3-one and 5-chloro-2-methyl-4-isothiazolin-3-one, each manufactured by The Dow Chemical Company, (KATHON and KORDEK are trademarks of DuPont de Nemours Inc.).

When biocides are included in the chemical mechanical polishing composition of the present invention, the biocides are included in amounts of 0.001wt % to 0.1wt %, preferably, 0.001wt % to 0.05wt %, more preferably, 0.001wt % to 0.01wt %, still more preferably, 0.001wt % to 0.005wt %.

Optionally, the chemical mechanical polishing composition can further include surfactants. Conventional surfactants can be used in the chemical mechanical polishing compositions. Such surfactants include, but are not limited to, non-ionic surfactants, anionic surfactants, cationic surfactants, amphoteric surfactants. Mixtures of such surfactants can also be used in the chemical mechanical polishing compositions of the present invention. Minor experimentation can be used to determine the type or combination of surfactants to achieve the desired viscosity of the chemical mechanical polishing composition.

Optionally, the chemical mechanical polishing compositions of the present invention can also include defoaming agents, such as non-ionic surfactants including esters, ethylene oxides, alcohols, ethoxylate, silicon compounds, fluorine compounds, ethers, glycosides and their derivatives. Anionic ether sulfates such as sodium lauryl ether sulfate (SLES) as well as the potassium and ammonium salts.

Surfactants and defoaming agents can be included in the chemical mechanical polishing compositions of the present invention in conventional amounts or in amounts tailored to provide the desired performance. For example, the chemical mechanical polishing composition can contain 0.0001wt % to 0.1wt %, preferably, 0.001wt % to 0.05wt %, more preferably, 0.01wt % to 0.05wt %, still more preferably, 0.01wt % to 0.025wt %, of a surfactant, defoaming agent or mixtures thereof.

The chemical mechanical polishing compositions can be used to polish various substrates. The modified silanized colloidal silica abrasive particles of the present invention are tunable for a given substrate or material, such as a dielectric. Such dielectric materials include, but are not limited to, TEOS and SiN. By changing the epoxysilane or the amine or a combination of the epoxysilane and amine of the modified silanized colloidal silica particle or by changing the pH of the chemical mechanical polishing compositions, as exemplified in the working examples below, the modified silanized colloidal silica particles can be tuned to achieve polishing selectivity, such as improving the polishing or RR of TEOS, SiN, or TEOS over SiN or alternatively, SiN over TEOS. Minor experimentation can be done to determine which combination of epoxysilanes and amines and amount of each and the pH can achieve the desired polishing performance for a given dielectric.

Preferably, the modified silanized colloidal silica abrasives of the present invention are included in chemical mechanical polishing compositions to polish TEOS, SiN or substrates comprising both TEOS and SiN. However, it is envisioned that the chemical mechanical polishing compositions can be used to polish metal materials, such as Cu, W, Ti, TiN, Ta, TaN, Co and other metals.

The polishing method of the present invention includes providing a chemical mechanical polishing pad, having a polishing surface; creating dynamic contact at an interface between the chemical mechanical polishing pad and the substrate; and dispensing the chemical mechanical polishing composition of the present invention onto the polishing surface of the chemical mechanical polishing pad at or near the interface between the chemical mechanical polishing pad and the substrate; wherein at least some dielectric material is polished away from the substrate.

Preferably, in the method of polishing a substrate with the chemical mechanical polishing composition of the present invention, the substrate comprises metal and a dielectric. More preferably, the substrate provided is a semiconductor substrate comprising metal and a dielectric, such as TEOS, SiN or combinations of the two dielectric materials. Most preferably, the substrate provided is a semiconductor substrate comprising metal deposited within at least one of holes and trenches formed in a dielectric such as TEOS.

Preferably, in the method of polishing a substrate of the present invention, the chemical mechanical polishing pad provided can by any suitable polishing pad known in the art. One of ordinary skill in the art knows to select an appropriate chemical mechanical polishing pad for use in the method of the present invention. More preferably, in the method of polishing a substrate of the present invention, the chemical mechanical polishing pad provided is selected from woven and non-woven polishing pads. Still more preferably, in the method of polishing a substrate of the present invention, the chemical mechanical polishing pad provided comprises a polyurethane polishing layer. Most preferably, in the method of polishing a substrate of the present invention, the chemical mechanical polishing pad provided comprises a polyurethane polishing layer containing polymeric hollow core microparticles and a polyurethane impregnated non-woven subpad. Preferably, the chemical mechanical polishing pad provided has at least one groove on the polishing surface.

Preferably, in the method of polishing a substrate of the present invention, the chemical mechanical polishing composition provided is dispensed onto a polishing surface of the chemical mechanical polishing pad provided at or near an interface between the chemical mechanical polishing pad and the substrate.

Preferably, in the method of polishing a substrate of the present invention, dynamic contact is created at the interface between the chemical mechanical polishing pad provided and the substrate with a down force of 0.69 to 34.5 kPa normal to a surface of the substrate being polished.

Preferably, in the method of polishing a substrate of the present invention, the chemical mechanical polishing composition of the present invention has a TEOS removal rate ≥400 Å/min; preferably, ≥1,000 Å/min; more preferably, ≥3,000 Å/min. Preferably, in the method of polishing a substrate of the present invention, the chemical mechanical polishing composition has a SiN removal rate of ≥100 Å/min; preferably, ≥500 Å/min; more preferably, ≥700 Å/min. Preferably, polishing is done with a platen speed of 223 revolutions per minute, a carrier speed of 221 revolutions per minute, a chemical mechanical polishing composition flow rate of 40 mL/min, a nominal down force of 27.6 kPa on a CETR polishing tool; and, wherein the chemical mechanical polishing pad comprises a polyurethane polishing layer containing polymeric hollow core microparticles and a polyurethane impregnated non-woven subpad.

The following examples are intended to further illustrate the present invention and are not intended to limit its scope.

### EXAMPLE 1

### Tunability of TEOS Removal Rates of Compositions of the Present Invention

A 50% by weight pre-hydrolyzed aqueous silane solutions was prepared by mixing equal weights of silane and DI water for 1 hr. For each slurry, silane surface modification was done by slowly adding the desired amount of the 50% pre-hydrolyzed aqueous silane solutions containing GPTMS into dispersions of Fuso BS-3 particles over a period of 5 min. DI water was then mixed with the silane modified Fuso BS-3 colloidal silica particles to make 18% by weight dispersions of the particles. The dispersions were then further aged at room temperature for at least 1 hr.

Aqueous amine solutions containing ethanolamine or butylamine were added into the above prepared particle dispersions with mixing. The dispersions were aged at room temperature for 5 days and then further aged at 55° C. for 24 hr. The dispersions were then diluted with DI water and pH was adjusted with 5% by weight HNO₃ solution to pH 4.5. The final particle concentration in the slurries was 2% by weight. The pH of the dispersions drifted towards higher pH values over a period of several days. The final pH value of the dispersions at the time of polishing was measured. The pH values are in Table 1 below.

Average particle size was measured using Malvern Zetasizer Nano ZS without further dilution. IEP was obtained by titration using ZetaAcoustic (ZA500) by Mass Applied Sciences.

The unit of the amount of silane and amine during particle preparation as listed in the table is number of molecules per nm² based on surface area of the Fuso BS-3 silica particles which was 78 m²/g as provided by FUSO Chemical Co., Ltd. The molecules per nm² for the silane and amine were determined using the following equation:

Ns=(Ws/Mw×NA)/(SSA×Wp×10¹⁸)
Ns: Number of GPTMS, ethanolamine or butylamine per nm² surface area of particle in number of molecules/nm²,
NA: Avogadro's number, 6.022×10²³ mol⁻¹,
Mw of GPTMS=236.34 g/mol,
Mw of ethanolamine=61.08 g/mol,
Mw of butylamine=73.14 g/mol,
SSA=78 m²/g,
Wp=2wt %,
Ws=as shown in Table 1

The TEOS polishing rates were obtained by polishing TEOS wafers (Pure Wafer, San Jose, Calif.) using a CETR polishing tool with VP6000-1010 pad at down-forces of 27.6 kPa, a platen/carrier speed of 223/221 rpm, and a slurry flow rate of 40 mL/min. The polishing pad was conditioned using Saesol AK45 Disk with 71b down-force for 3 min during Break-In and 30 sec ex situ for each polishing wafer. TEOS polishing removal rates, along with physical properties of the polishing compositions are listed in Table 1.

TABLE 1

| | | | | | | | Mean Particle | | |
|---|---|---|---|---|---|---|---|---|---|
| | | GPTMS, | Amine | | Amine, | | Size | | TEOS RR |
| Example | GPTMS/nm² | wt % | type | Amine/nm² | wt % | pH | (nm) | IEP | (Å/min) |
| Ex1-1 | 0.3 | 0.0184% | EOA | 0.1 | 0.0016% | 4.73 | 64 | 6.03 | 4843 |
| Ex1-2 | 0.3 | 0.0184% | EOA | 0.2 | 0.0032% | 4.81 | 64 | | 3599 |
| Ex1-3 | 0.3 | 0.0184% | EOA | 0.3 | 0.0047% | 4.98 | 65 | 5.85 | 1411 |
| Ex1-4 | 0.3 | 0.0184% | EOA | 0.4 | 0.0063% | 4.96 | 65 | | 446 |
| Ex1-5 | 0.6 | 0.0367% | EOA | 0.2 | 0.0032% | 4.88 | 67 | | 3421 |
| Ex1-6 | 0.6 | 0.0367% | EOA | 0.4 | 0.0063% | 4.99 | 68 | | 3637 |
| Ex1-7 | 0.6 | 0.0367% | EOA | 0.5 | 0.0079% | 5.00 | 69 | 6.94 | 3866 |
| Ex1-8 | 0.6 | 0.0367% | EOA | 0.6 | 0.0095% | 5.05 | 69 | 6.74 | 3947 |
| Ex1-9 | 0.6 | 0.0367% | EOA | 0.8 | 0.0127% | 5.16 | 71 | | 0 |
| Ex1-10 | 0.3 | 0.0184% | BA | 0.2 | 0.0038% | 5.01 | 70 | | 3988 |
| Ex1-11 | 0.3 | 0.0184% | BA | 0.3 | 0.0057% | 4.66 | 69 | 5.46 | 3068 |

GPTMS: 3-glycidoxypropyltrimethoxysilane
EOA: Ethanolamine
BA: Butylamine

IEP and particle size data showed that all the compositions were well dispersed with mean particle sizes in the range of 64-71 nm.

The polishing data showed that TEOS removal rates of the compositions of the invention are highly tunable by varying the amount of GPTMS and amines independently, as shown in the Table 1.

The data showed that TEOS removal rates first increased with the amount of amine reacted with the epoxy functionality of the epoxy moiety of GPTMS. TEOS removal rates started to drop as the amount of amine added increased.

While not being bound by theory, it is believed that excessive free amine in the polishing compositions did not react with the epoxy functionality and instead adsorbed onto the TEOS substrate reducing the attraction between the positively charged particles and the negatively charged TEOS substrate, thus lowering the removal rates.

### EXAMPLE 2

### Tunability of TEOS and SiN Removal Rates of Polishing Compositions of the Invention

A plurality of 50% pre-hydrolyzed aqueous silane solutions were prepared by mixing equal amounts of silane and DI water for 1 hr. Silane surface modification was done by slowly adding the 50% pre-hydrolyzed aqueous silane solutions containing GPTMS into dispersions of Fuso BS-3 particles over a period of 5 min. DI water was then mixed with the silane modified Fuso BS-3 colloidal silica particles to make 18% by weight dispersions. The dispersions were then further aged at room temperature for an 1 hr.

Amine solutions of 10wt % were added into the above prepared particle dispersions with mixing. The dispersions were aged at room temperature for 1 hr and then further aged at 55° C. for 24 hr.

The amount of silane during particle preparation was 0.6 molecule per nm². The amount of amine during particle preparation was 0.5 molecule per nm². The number of molecules per nm² was based on the surface area of the Fuso BS-3 silica particles which was 78 m²/g.

The dispersions of modified particles were then diluted with DI water and the pH was adjusted with 5% HNO₃ solution to be below the IEP to reverse the charge of the particles from negative to positive. IEP was obtained by titration using ZetaAcoustic (ZA500) by Mass Applied Sciences.

The final particle concentration in the slurries was 2% by weight. Any additional pH adjustment to maintain the pH of the slurries below the IEP was done with 5% by weight HNO₃ or 5% by weight KOH. The final pH value of the slurries at the time of polishing was measured. The pH values are in Table 2.

The TEOS and SiN polishing rates were obtained by polishing the wafers using a CETR polishing tool with VP6000-1010 pad at down-forces of 27.6 kPa, a platen/carrier speed of 223/221 rpm, and a slurry flow rate of 40 mL/min. The polishing pad was conditioned using

Saesol AK45 Disk with 71b down-force for 3 min during Break-In and 30 sec ex situ for each polishing wafer. TEOS and SiN polishing removal rates and TEOS/SiN selectivity are listed in Table 2.

TABLE 2

| | | | | | TEOS RR, | SiN RR, | TEOS/SiN |
|---|---|---|---|---|---|---|---|
| Example | Silane | Amine | pH | IEP | (Å/min) | (Å/min) | Selectivity |
| Ex2-1 | GPTMS | EOA | 4.77 | 6.61 | 3770 | 483 | 7.8 |
| Ex2-2 | GPTMS | EOA | 5.80 | | 3218 | 217 | 14.9 |
| Ex2-3 | GPTMS | DMAPA | 4.76 | 8.08 | 856 | 200 | 4.3 |
| Ex2-4 | GPTMS | DMAPA | 5.81 | | 2517 | 838 | 3.0 |
| Ex2-5 | GPTMS | DMAPA | 6.67 | 8.09 | 1745 | 755 | 2.3 |
| Ex2-6 | GPTMS | EDA | 4.91 | 7.53 | 2662 | 190 | 14.0 |
| Ex2-7 | GPTMS | EDA | 5.88 | 7.74 | 2882 | 907 | 3.2 |
| Ex2-8 | GPTMS | EDA | 6.55 | | 2465 | 652 | 3.8 |

GPTMS: 3-glycidoxypropyltrimethoxysilane
EOA: Ethanolamine
DMAPA: Dimethylaminopropylamine
EDA: Ethylenediamine

The polishing data showed that both SiN and TEOS removal rates of compositions of the invention were tunable by varying the type of amines and the pH of the slurries.

The data showed that the polishing compositions using the combination of GPTMS and diamines EDA and DMAPA showed increased SiN removal rates as the pH values increased with a slight increase in the TEOS/SiN selectivity for Ex2-8 at pH=6.55. Lower TEOS/SiN selectivity are often desirable in removing interlayer dielectrics during CMP processes.

### EXAMPLE 3

### Ethylenediamine Reactions with Glycidoxysilane Coated Silica Particles

A plurality of 50% pre-hydrolyzed aqueous silane solutions were prepared by mixing equal amounts of silane and DI water (wt/wt) for 1 hr. Silane surface modification of colloidal silica particles was then done by slowly adding the 50% pre-hydrolyzed aqueous silane solutions into colloidal silica particle dispersions over a period of 5 min. DI water was then mixed with the silane modified colloidal silica particles to make particle concentrations of 18% by weight. The dispersions were then further aged at room temperature for 30 min to 1 hr before adding amines.

Aqueous amine solutions were added to the above prepared silane surface modified colloidal silica particle dispersions with mixing.

The total amount of silane and amine added to the solutions during particle preparation was converted into surface coverage on silica particles using the equation as in Example 1. The unit of surface coverage is number of molecules per nm² based on surface area of Fuso BS-3 or SH-3 silica particles being 78 m²/g as provided by FUSO Chemical Co., Ltd.

The dispersions were then further aged at 55° C. for 20 hrs. The modified silica particles were then separated using ultracentrifugation with a Sorvall MTX 150 Ultra-Centrifuge, 90K rpm, 45 min, 25° C.

Free amines in the supernatants were analyzed using Ion Chromatograph with the following process details:
Instrument: Dionex ICS 5000⁺ System
Column: Dionex IonPac® CS-17 2×250 mm, CG-17 2×50 mm
Column Temp: 30° C.
Detection: Suppressed Conductivity
Suppressor current: CERS 2 mm Suppressor at 5 mA
Injection Vol: 10 μL
Eluent: 6 mM methane sulfonic acid delivered via Dionex EG System

A calibration curve consisting of 3 standards and a blank with correlation coefficient of 0.99 or greater was established before the sample or series of samples were run. Each sample was run twice with the difference between two runs less than 10%. The final amine concentration was the average of two runs.

Results are shown in Table 3.

TABLE 3

| | | | | GPTMS | EDA | Free EDA in | |
|---|---|---|---|---|---|---|---|
| | Particle | | | added, | added, | supernatant, | Free |
| Composition | Type | GPTMS/nm² | EDA/nm² | ppm | ppm | ppm | EDA % |
| Ex3-1 | Fuso BS-3 | 0.45 | 0.35 | 2478 | 490.0 | 9.1 | 1.9% |
| Ex3-1 | Fuso BS-3 | 0.6 | 0.5 | 3304 | 700.1 | 36.2 | 5.2% |
| Ex3-2 | Fuso SH-3 | 0.45 | 0.35 | 2478 | 490.0 | 54.2 | 11.1% |
| Ex3-3 | Fuso SH-3 | 0.45 | 0.45 | 2478 | 630.1 | 87.4 | 13.9% |
| Ex3-4 | Fuso SH-3 | 0.6 | 0.5 | 3304 | 700.1 | 99.3 | 14.2% |
| Ex3-5 | Fuso SH-3 | 0.6 | 0.6 | 3304 | 840.1 | 131.5 | 15.7% |

GPTMS: 3-glycidoxypropyltrimethoxysilane
EDA: Ethylenediamine

Results showed that relatively small amounts of amine remained free in the dispersions after reacting the amines with the GPTMS modified particles. Substantially all the amine reacted with the epoxy functionality of the GPTMS modified particles.

What is claimed is:

1. A silanized colloidal silica particle comprising a reaction product of an epoxy functionality of the silanized colloidal silica particle with a nitrogen of an amine.

2. The silanized colloidal silica particle of claim 1, wherein the amine is selected from the group consisting of ethanolamine, N-methylethanolamine, butylamine, dibutylamine, 3-ethoxypropylamine, ethylenediamine, N,N-dimethylethylenediamine, 3-(dimethylamino)-1-propylamine, 3-(diethylamino) propylamine, (2-aminoethyl) trimethylammonium chloride hydrochloride, triethylenetetramine, teraethylenepentamine, pentaethylenehexamine, guanidine, guanidine acetate and 1,1,3,3-tetramethylguanidine.

3. The silanized colloidal silica particle of claim 1, wherein the silanized colloidal silica particle has the structure: 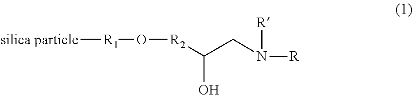
wherein R₁ and R₂ are independently chosen from linear or branched C₁-C₅ alkylene; R and R′ are independently chosen from hydrogen, linear or branched C₁-C₄ alkyl, linear or branched hydroxy C₁-C₄ alkyl, linear or branched alkoxy C₁-C₄ alkyl, quaternary amino C₁-C₄ alkyl, substituted or unsubstituted, linear or branched amino C₁-C₄ alkyl, wherein substituent groups on the substituted amino C₁-C₄ alkyl include linear or branched C₁-C₄ alkyl on a nitrogen of the amino C₁-C₄ alkyl, substituted or unsubstituted guanidyl group, wherein substituent groups on the substituted guanidyl group are chosen from C₁-C₂ alkyl on a nitrogen of the guanidyl group, and R′ and R independently can be a moiety having the formula:
H₂N—[—(CH₂)ₙ—NH—]ₘ—(CH₂)ₙ— (II)
wherein n and m are independently integers from 2-4; and R and R′ can be taken together with their atoms to form a substituted or unsubstituted heterocyclic nitrogen and carbon six membered ring, wherein substituent groups are chosen from C₁-C₂ alkyl groups.

4. A chemical mechanical polishing composition comprising a silanized colloidal silica particle comprising a reaction product of an epoxy functionality of the silanized colloidal silica particle with a nitrogen of an amine;
water;
optionally an oxidizing agent;
optionally a complexing agent;
optionally a source of iron (III) ions;
optionally a corrosion inhibitor;
optionally a surfactant;
optionally a defoaming agent;
optionally biocide; and
optionally a pH adjustor.

5. The chemical mechanical polishing compositions of claim 4, wherein the silanized colloidal silica particle has the structure: 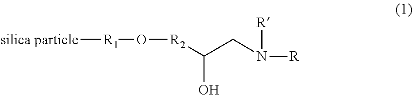
wherein R₁ and R₂ are independently chosen from linear or branched C₁-C₅ alkylene; R and R′ are independently chosen from hydrogen, linear or branched C₁-C₄ alkyl, linear or branched hydroxy C₁-C₄ alkyl, linear or branched alkoxy C₁-C₄ alkyl, quaternary amino C₁-C₄ alkyl, substituted or unsubstituted, linear or branched amino C₁-C₄ alkyl, wherein substituent groups on the substituted amino C₁-C₄ alkyl include linear or branched C₁-C₄ alkyl on a nitrogen of the substituted amino C₁-C₄ alkyl, substituted or unsubstituted guanidyl group, wherein substituent groups on the substituted guanidyl group are chosen from C₁-C₂ alkyl on a nitrogen of the substituted guanidyl group, and R′ and R independently can be a moiety having the formula:
H₂N—[—(CH₂)ₙ—NH—]ₘ—(CH₂)ₙ— (II)
wherein n and m are independently integers from 2-4; and R and R′ can be taken together with their atoms to form a substituted or unsubstituted heterocyclic nitrogen and carbon six membered ring, wherein substituent groups are chosen from C₁-C₂ alkyl groups.

6. A chemical mechanical polishing method comprising: providing a substrate comprising a metal and a dielectric;
providing a chemical mechanical polishing composition comprising a silanized colloidal silica particle, wherein the silanized colloidal silica particle comprises a reaction product of an epoxy functionality of the silanized colloidal silica particle with a nitrogen of an amine;
water;
optionally an oxidizing agent;
optionally a complexing agent;
optionally a source of iron (III) ions;
optionally a corrosion inhibitor;
optionally a surfactant;
optionally a defoaming agent;
optionally biocide; and
optionally a pH adjustor;
providing a chemical mechanical polishing pad, having a polishing surface; creating dynamic contact at an interface between the chemical mechanical polishing pad and the substrate; and dispensing the chemical mechanical polishing composition onto the polishing surface of the chemical mechanical polishing pad at or near the interface between the chemical mechanical polishing pad and the substrate; wherein some of the metal or some of the dielectric or portions of the metal and dielectric are polished away from the substrate.

7. The chemical mechanical polishing method of claim 6, wherein the silanized colloidal silica particle has the structure: 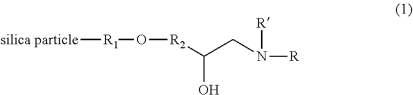
wherein R₁ and R₂ are independently chosen from linear or branched C₁-C₅ alkylene; R and R′ are independently chosen from hydrogen, linear or branched C₁-C₄ alkyl, linear or branched hydroxy C₁-C₄ alkyl, linear or branched alkoxy C₁-C₄ alkyl, quaternary amino C₁-C₄ alkyl, substituted or unsubstituted, linear or branched amino C₁-C₄ alkyl, wherein substituent groups on the substituted amino C₁-C₄ alkyl include linear or branched C₁-C₄ alkyl on a nitrogen of the substituted amino C₁-C₄ alkyl, substituted or unsubstituted guanidyl group, wherein substituent groups on the substituted guanidyl group are chosen from C₁-C₂ alkyl on a nitrogen of the substituted guanidyl group, and R′ and R independently can be a moiety having the formula:
H₂N—[—(CH₂)ₙ—NH—]ₘ—(CH₂)ₙ— (II)
wherein n and m are independently integers from 2-4; and R and R′ can be taken together with their atoms to form a substituted or unsubstituted heterocyclic nitrogen and carbon six membered ring, wherein substituent groups are chosen from C₁-C₂ alkyl groups.
